(19) United States
(12) Patent Application Publication
(10) Pub. No.: US 2026/0304004 A1
(43) Pub. Date: Oct. 1, 2026

(54) RAMP GENERATOR

(71) Applicant: SK hynix Inc., Gyeonggi-do (KR)

(72) Inventor: Won Seok HWANG, Gyeonggi-do (KR)

(21) Appl. No.: 19/393,577

(22) Filed: Nov. 19, 2025

(30) Foreign Application Priority Data
Feb. 3, 2025 (KR) 10-2025-0013249

(51) Int. Cl. H04N 25/78; H04N 25/60

(52) U.S. Cl. CPC H04N 25/78; H04N 25/60

(57) ABSTRACT

A ramp generator is provided. The ramp generator includes a pull-up current generator configured to generate a pull-up current; a pull-down current generator configured to generate a pull-down current; and a variable resistor circuit, one end of which is connected between the pull-up current generator and the pull-down current generator and configured to output a ramp signal, and another end of which is configured to receive a common voltage.

### CROSS-REFERENCE TO RELATED APPLICATIONS

This patent document claims the priority and benefits of Korean patent application No. 10-2025-0013249, filed on Feb. 3, 2025, the disclosure of which is incorporated herein by reference in its entirety as part of the disclosure of this patent document.

### TECHNICAL FIELD

The technology and implementations disclosed in this patent document generally relate to a ramp generator for generating a ramp signal.

### BACKGROUND

An image sensing device is a device for capturing optical images by converting light into electrical signals using a photosensitive semiconductor material which reacts to light. With the development of automotive, medical, computer, and communication industries, the demand for high-performance image sensing devices is increasing in various fields such as smartphones, digital cameras, game machines, Internet of Things (IoT), robots, security cameras and medical micro cameras.

An image sensing device may require a ramp generator configured to generate a ramp signal. The ramp signal may include noise, and in order to improve performance of the image sensing device it may be necessary to reduce the noise of the ramp signal.

### SUMMARY

Various embodiments of the present disclosure provide a ramp generator for reducing noise of a ramp signal.

Various embodiments of the present disclosure provide a ramp generator for changing a noise distribution of the ramp signal.

In accordance with an embodiment of the present disclosure, a ramp generator may include: a pull-up current generator configured to generate a pull-up current; a pull-down current generator configured to generate a pull-down current; and a variable resistor circuit, one end of which is connected between the pull-up current generator and the pull-down current generator and configured to output a ramp signal, and another end of which is configured to receive a common voltage.

In some implementations, the pull-up current generator may include a plurality of pull-up current cells; and the pull-down current generator may include a plurality of pull-down current cells.

In some implementations, the ramp generator further comprises: a decoder circuit configured to control operations of the pull-up current generator and the pull-down current generator. The decoder circuit may turn on at least a portion of the pull-up current cells and may then sequentially turn off the turned-on portion of the pull-up current cells.

In some implementations, the decoder circuit may sequentially turn on at least a portion of the pull-down current cells, in response to a determination that all of the pull-up current cells are turned off.

In some implementations, the decoder circuit may control operations of the pull-up current generator and the pull-down current generator based on a noise distribution of the ramp signal.

In some implementations, the decoder circuit may reduce a number of pull-up current cells to be turned on, in response to a decrease in a magnitude of a first noise required at a start point of the ramp signal.

In some implementations, the decoder circuit may increase a number of pull-up current cells to be turned on, in response to a decrease in a magnitude of a second noise required at an end point of the ramp signal.

In some implementations, in response to a determination that a magnitude of a third noise required at a midpoint between a start point and an end point of the ramp signal is at a minimum value, the decoder circuit may control the pull-up current generator and the pull-down current generator such that a number of pull-up current cells to be turned on is equal to a number of pull-down current cells to be turned on.

In some implementations, the pull-up current generator may receive a power-supply voltage; and the pull-down current generator may receive a ground voltage.

In some implementations, the variable resistor circuit may have a resistance value that varies depending on a gain required by an image sensing device.

In some implementations, the variable resistor circuit may be configured to have a smaller resistance value as a magnitude of the required gain increases.

In accordance with another embodiment of the present disclosure, a ramp generator may include: a plurality of pull-up current cells configured to receive a power-supply voltage; a plurality of pull-down current cells configured to receive a ground voltage; and a variable resistor, one end of which is connected between the pull-up current cells and the pull-down current cells and configured to output a ramp signal, and another end of which is configured to receive a common voltage.

In some implementations, the ramp generator further comprises a decoder connected to the pull-up current cells and the pull-down current cells. The decoder may turn on at least a portion of the pull-up current cells and may then sequentially turn off the turned-on portion of the pull-up current cells.

In some implementations, the decoder may sequentially turn on at least a portion of the pull-down current cells, in response to a determination that all of the pull-up current cells are turned off.

In some implementations, the decoder may control operations of the pull-up current cells and the pull-down current cells based on a noise distribution of the ramp signal.

In some implementations, the decoder may reduce a number of pull-up current cells to be turned on, in response to a decrease in a magnitude of a first noise required at a start point of the ramp signal.

In some implementations, the decoder may increase a number of pull-up current cells to be turned on, in response to a decrease in a magnitude of a second noise required at an end point of the ramp signal.

In some implementations, in response to a determination that a magnitude of a third noise required at a midpoint between a start point and an end point of the ramp signal is at a minimum value, the decoder may control a number of pull-up current cells to be turned on to be equal to a number of pull-down current cells to be turned on.

In some implementations, the variable resistor may have a resistance value that varies depending on a gain required by the image sensing device.

In accordance with another embodiment of the present disclosure, a ramp generator may include: a plurality of pull-up current cells configured to receive a power-supply voltage; a plurality of pull-down current cells configured to receive a ground voltage; a variable resistor having one end configured to output a ramp signal and another end configured to receive an applied common voltage, such that a resistance value of the variable resistor is determined based on a number of the pull-up current cells to be turned on and a number of the pull-down current cells to be turned on; and a decoder configured to control operations of the pull-up current cells and the pull-down current cells.

It is to be understood that both the foregoing general description and the following detailed description of the present disclosure are illustrative and explanatory and are intended to provide further explanation of the present disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an example of an imaging device according to an embodiment of the present disclosure.

FIG. 2 is a block diagram illustrating an example of a ramp generator according to an embodiment of the present disclosure.

FIG. 3 is a diagram illustrating an example of a ramp generator according to an embodiment of the present disclosure.

FIG. 4 is a diagram illustrating an example of a ramp signal according to an embodiment of the present disclosure.

FIG. 5A and FIG. 5B are diagrams illustrating example operations of the ramp generator according to an embodiment of the present disclosure.

FIG. 6A and FIG. 6B are diagrams illustrating an example of noise distribution of the ramp signal according to a comparative example.

FIG. 7 is a diagram illustrating an example of the noise distribution of the ramp signal according to an embodiment of the present disclosure.

FIG. 8 is a diagram illustrating an example of the noise distribution of the ramp signal according to an embodiment of the present disclosure.

### DETAILED DESCRIPTION

Embodiments of the present disclosure are directed to implementations and examples of a ramp generator for generating a ramp signal that may be used in configurations to substantially address one or more technical or engineering issues and to mitigate limitations or disadvantages encountered in some other ramp generators. Some implementations of the present disclosure relate to a ramp generator for reducing noise of a ramp signal. Some implementations of the present disclosure relate to a ramp generator for changing a noise distribution of the ramp signal. In recognition of the issues above, the present disclosure may provide the ramp generator that can reduce noise of the ramp signal. The present disclosure may provide the ramp generator that can change the noise distribution of the ramp signal.

Reference will now be made in detail to the embodiments of the present disclosure, examples of which are illustrated in the accompanying drawings. Wherever possible, the same reference numbers will be used throughout the drawings to refer to the same or like parts. While the present disclosure is susceptible to various modifications and alternative forms, specific embodiments thereof are shown by way of example in the drawings. However, the present disclosure should not be construed as being limited to the embodiments set forth herein.

Hereinafter, various embodiments will be described with reference to the accompanying drawings. However, it should be understood that the present disclosure is not limited to specific embodiments, but includes various modifications, equivalents and/or alternatives of the embodiments. The embodiments of the present disclosure may provide a variety of effects capable of being directly or indirectly recognized through the present disclosure.

Hereinafter, embodiments of the present disclosure will be described in detail with reference to the accompanying drawings so that the present disclosure may be easily realized by those skilled in the art. However, the present disclosure may be achieved in various different forms and is not limited to the embodiments described herein.

In the following description of embodiments of the present disclosure, a detailed description of known functions and configurations incorporated herein will be omitted when it may make the subject matter of the present disclosure rather unclear. In the drawings, parts that are not related to a description of the present disclosure are omitted to clearly explain the present disclosure and similar reference numbers will be used throughout this specification to refer to similar parts.

In the present disclosure, when a component is referred to as being “connected”, “coupled”, or “joined” to another component, it may include not only a direct connection relationship but also an indirect connection relationship in which another component is present therebetween. In addition, when a component “comprises”, “includes” or “has” another component, this means that the component does not exclude other components unless specifically stated above but may further include other components.

In the present disclosure, terms such as “first”, “second”, etc. are used only to distinguish one element from other elements and is not used to limit elements, and unless otherwise specified, it does not limit an order or importance, etc., of elements. Accordingly, within a scope of the present disclosure, a first element in an embodiment may be referred to as a second element in another embodiment and likewise, a second element in an embodiment may be referred to as a first element in another embodiment.

In the following description, components are discriminated from each other to clearly describe their characteristics, but this does not mean that they are necessarily physically separated. That is, a plurality of components may be integrated into one hardware or software module and one component may be divided into a plurality of hardware or software modules. Accordingly, integrated or divided embodiments are within the scope of the present disclosure even if not specifically stated.

In the following description, components described with reference to various embodiments are not all necessarily required and some components may be selectively used. Accordingly, embodiments composed of some of the components described in one embodiment are also within the scope of the present disclosure. Further, embodiments implemented by adding components to various embodiments are also within the scope of the present disclosure.

In the present disclosure expressions of positional relationships used in the present specification such as “top”, “upper”, “bottom”, “lower”, “left”, “right”, etc., are employed for the convenience of explanation, and when the drawings illustrated in the present specification are viewed in reverse, the positional relationships described in the specification may be interpreted in the opposite way.

In the present disclosure, each of phrases such as “A or B”, “at least one of A and B”, “at least one of A or B”, “A, B or C”, “at least one of A, B and C”, “and “at least one of A, B, or C” may include any one or all possible combinations of the items listed together in the corresponding one of the phrases. In description of the present disclosure, the term “and/or” may include a combination of a plurality of items or any one of a plurality of listed items. For example, “A or B” may include “only A”, “only B”, or “both A and B”.

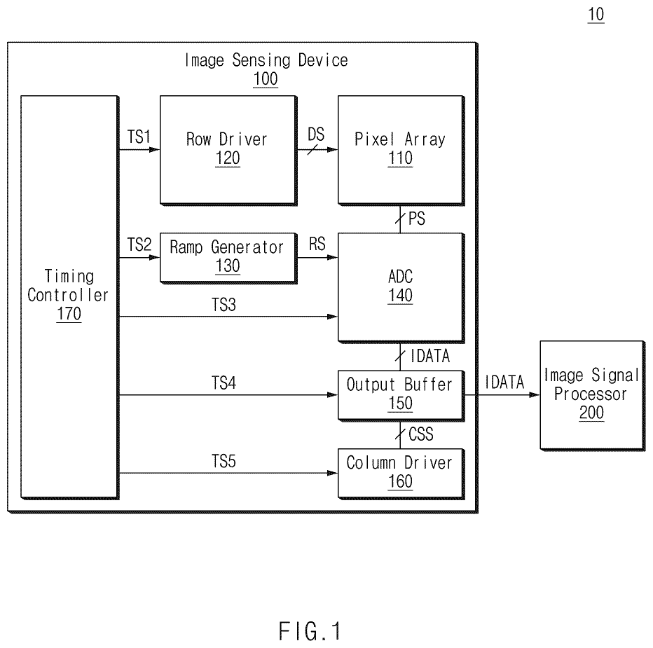

Hereinafter, embodiments of the present disclosure will be specifically described with reference to FIGS. 1 to 8.

FIG. 1 is a block diagram illustrating an example of an imaging device 10 according to an embodiment of the present disclosure.

Referring to FIG. 1, the imaging device 10 may refer to a device, for example, a digital still camera for photographing still images or a digital video camera for photographing moving images. For example, the imaging device 10 may be implemented as a Digital Single Lens Reflex (DSLR) camera, a mirrorless camera, or a smartphone, and others. The imaging device 10 may include a device having both a lens and an image pickup element such that the device can capture (or photograph) a target object and can thus create an image of the target object.

The imaging device 10 may include an image sensing device 100 and an image signal processor (ISP) 200.

The image sensing device 100 may be a complementary metal oxide semiconductor image sensor (CIS) for converting an incident light into an electrical signal. The image sensing device 100 may include a pixel array 110, a row driver 120, a ramp generator 130, an analog-to-digital converter (ADC) 140, an output buffer 150, a column driver 160, and a timing controller 170. The components of the image sensing device 100 illustrated in FIG. 1 are discussed by way of example only, and the present disclosure encompasses numerous other changes, substitutions, variations, alterations, and modifications.

The pixel array 110 may include a plurality of pixels arranged in rows and columns. In one example, the plurality of pixels can be arranged in a two-dimensional (2D) pixel array including rows and columns. In another example, the plurality of image pixels may be arranged in a three-dimensional (3D) pixel array. The plurality of pixels may convert an optical signal into an electrical signal on a pixel basis or a pixel group basis, where the pixels in a pixel group share at least certain internal circuitry. The pixel array 110 may receive driving signals (DS), including a row selection signal, a pixel reset signal and a transfer signal, from the row driver 120. Upon receiving the driving signals (DS), corresponding imaging pixels in the pixel array 110 may be activated to perform the operations corresponding to the row selection signal, the pixel reset signal, and the transfer signal.

Each pixel (PX) in the pixel array 110 may have at least two different sensitivities. Here, the sensitivity may mean an increase in amount of image data IDATA (or an increase amount of a response) with respect to an increase in amount of the intensity of incident light. That is, as the sensitivity increases, the amount of increase in image data (IDATA) in response to an increase in the intensity of incident light increases. As the sensitivity decreases, the amount of increase in image data (IDATA) in response to an increase in the intensity of incident light decreases. In the present disclosure, the sensitivity may be determined by a conversion gain.

The row driver 120 may activate the pixel array 110 to perform certain operations on the pixels included in the corresponding row based on commands and control signals provided by the timing controller 170. In some implementations, the row driver 120 may select one or more imaging pixels arranged in one or more rows of the pixel array 110. The row driver 120 may generate a row selection signal to select one or more rows among the plurality of rows. The row driver 120 may sequentially enable the pixel reset signal for resetting the pixels corresponding to at least one selected row, and the transfer signal for the pixels corresponding to the at least one selected row. Thus, a reference signal and an image signal, which are analog signals generated by each of the pixels of the selected row, may be sequentially transferred to the ADC 140. The reference signal may be an electrical signal that is provided to the ADC 140 when a sensing node of a pixel (e.g., a floating diffusion region) is reset, and the image signal may be an electrical signal that is provided to the ADC 140 when photocharges generated by the pixel are accumulated in the sensing node. The reference signal indicating unique reset noise of each pixel and the image signal indicating the intensity of incident light may be alternatively referred to as a pixel signal.

The CMOS image sensor may use the correlated double sampling (CDS) to remove undesired offset values of pixels known as the fixed pattern noise by sampling a pixel signal twice to remove the difference between these two samples. In one example, the correlated double sampling (CDS) may remove the undesired offset value of pixels by comparing pixel output voltages obtained before and after photocharges generated by incident light are accumulated in the sensing node so that only pixel output voltages based on the incident light can be measured. In some implementations, the ADC 140 may sequentially sample and hold voltage levels of the reference signal and the image signal, which are provided to each of a plurality of column lines from the pixel array 110.

The ramp generator 130 may generate a ramp signal (RS) required for the analog-to-digital conversion operation of the ADC 140 upon receiving a timing signal (TS2) from the timing controller 170, and may supply the ramp signal to the ADC 140.

The ADC 140 may sample and hold the pixel signal from each column line of the pixel array 110 based on a timing signal (TS3) of the timing controller 170, may convert the resultant signal into digital signals, and may output the digital signals. In some implementations, the ADC 140 may be implemented as a ramp-compare type ADC. The ramp-compare type ADC may include a comparator circuit for comparing the analog pixel signal with a ramp signal that ramps up or down according to time, and a counter for performing counting until a voltage of the ramp signal matches the analog pixel signal.

The output buffer 150 may temporarily hold the column-based image data (i.e., data (IDATA) obtained through digital conversion of the pixel signal) provided from the ADC 140 to output the image data. In one example, the image data provided to the output buffer 150 from the ADC 140 may be temporarily stored in the output buffer 150 based on a timing signal (TS4) of the timing controller 170. The output buffer 150 may provide an interface to compensate for data rate differences or transfer rate differences between the image sensing device 100 and other devices.

The column driver 160 may select a column of the output buffer 150 upon receiving a control signal (TS5) from the timing controller 170, and may sequentially output the image data (IDATA), which are temporarily stored in the selected column of the output buffer 150. In some implementations, upon receiving an address signal from the timing controller 170, the column driver 160 may generate a column selection signal (CSS) based on the address signal and may select a column of the output buffer 150, thereby outputting the image data (IDATA) as an output signal from the selected column of the output buffer 150.

The timing controller 170 may control operations of at least one of the row driver 120, the ramp generator 130, the ADC 140, the output buffer 150, and the column driver 160.

The timing controller 170 may provide at least one of the row driver 120, the ramp generator 130, the ADC 140, the output buffer 150, and the column driver 160 with a clock signal required for the operations of the respective components of the image sensing device 100, a control signal for timing control, and address signals for selecting a row or column. In some embodiments, the timing controller 170 may include a logic control circuit, a phase-locked loop (PLL) circuit, a timing control circuit, a communication interface circuit and others.

The image signal processor (ISP) 200 may perform image processing of image data received from the image sensing device 100. The image signal processor (ISP) 200 may reduce noise of image data, and may perform various kinds of image signal processing (e.g. interpolation, synthesis, gamma correction, color filter array interpolation, color matrix, color correction, color enhancement, lens distortion correction, etc.) for image-quality improvement of the image data. In addition, the image signal processor (ISP) 200 may compress image data that has been created by execution of image signal processing for image-quality improvement, such that the image signal processor (ISP) 200 can create an image file using the compressed image data. Alternatively, the image signal processor (ISP) 200 may recover image data from the image file. In this case, the scheme for compressing such image data may be a reversible format or an irreversible format. As a representative example of such compression format, in the case of using a still image, Joint Photographic Experts Group (JPEG) format, JPEG 2000 format, or the like can be used. In addition, in the case of using moving images, a plurality of frames can be compressed according to Moving Picture Experts Group (MPEG) standards such that moving image files can be created. For example, the image files may be created according to Exchangeable image file format (Exif) standards.

The image signal processor (ISP) 200 may generate an HDR image by synthesizing at least two images having different sensitivities. For example, the image sensing device 100 may output a low-sensitivity image generated from a low-sensitivity pixel (e.g., a low conversion gain (LCG) pixel) with a relatively lower sensitivity and a high-sensitivity image generated from a high-sensitivity pixel (e.g., a high conversion gain (HCG) pixel) with a relatively higher sensitivity. The image signal processor (ISP) 200 may combine the low-sensitivity image and the high-sensitivity image, resulting in formation of an HDR image. Here, the low-sensitivity and the high-sensitivity may correspond to relative concepts, and the image sensing device 100 may generate image data (IDATA) having at least N different sensitivities (where N is an integer of 2 or more). The image signal processor (ISP) 200 may generate HDR images using the image data (IDATA).

The image signal processor (ISP) 200 may transmit the ISP image data to a host device (not shown). The host device (not shown) may be a processor (e.g., an application processor) for processing the ISP image data received from the image signal processor (ISP) 200, a memory (e.g., a non-volatile memory) for storing the ISP image data, or a display device (e.g., a liquid crystal display LCD) for visually displaying the ISP image data.

In addition, the image signal processor (ISP) 200 may transmit a control signal for controlling operations (e.g., whether or not to operate, an operation timing, an operation mode, etc.) of the image sensing device 100, to the image sensing device 100.

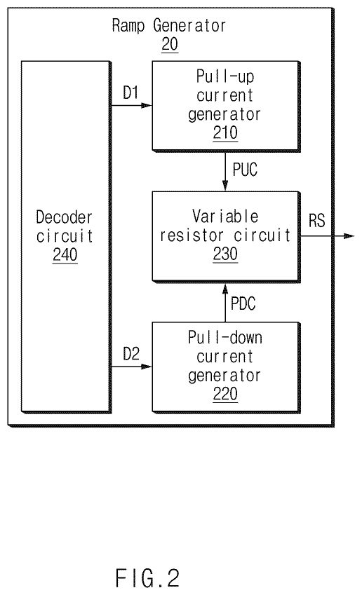

FIG. 2 is a block diagram illustrating an example of a ramp generator 20 based on some embodiments of the present disclosure.

Referring to FIG. 2, the ramp generator 20 may include a pull-up current generator 210, a pull-down current generator 220, a variable resistor circuit 230, and a decoder circuit 240. The ramp generator 20 of FIG. 2 may be an embodiment of the ramp generator 130 of FIG. 1.

The pull-up current generator 210 may generate a pull-up current (PUC). For example, the pull-up current generator 210 may include a plurality of pull-up current cells configured to generate the pull-up current (PUC). The pull-up current (PUC) may be generated when at least a portion of the pull-up current cells in the pull-up current generator 210 are turned on. In addition, as the turned-on pull-up current cells in the pull-up current generator 210 are sequentially turned off, the magnitude of the pull-up current (PUC) may gradually decrease.

The pull-down current generator 220 may generate a pull-down current (PDC). For example, the pull-down current generator 220 may include a plurality of pull-down current cells configured to generate the pull-down current (PDC). The pull-down current (PDC) may be generated when at least a portion of the pull-down current cells in the pull-down current generator 220 are sequentially turned on. In addition, as the turned-off pull-down current cells of the pull-down current generator 220 are sequentially turned on, the magnitude of the pull-down current (PDC) may gradually increase.

The variable resistor circuit 230 may include a variable resistor. In addition, the variable resistor circuit 230 may be connected between the pull-up current generator 210 and the pull-down current generator 220. The variable resistor circuit 230 may output a ramp signal (RS). A common voltage may be applied to the variable resistor circuit 230. The resistance value of the variable resistor circuit 230 may vary depending on a gain of the image sensing device 100. For example, the variable resistor circuit 230 may have a smaller resistance value as the required gain increases, but the scope of the present disclosure is not limited thereto. In addition, the variable resistor circuit 230 may change a resistance value thereof based on the number of turned-on pull-up current cells and the number of turned-on pull-down current cells. For example, as the total number of turned-on pull-up current cells and turned-on pull-down current cells increases, the resistance value of the variable resistor circuit 230 may decrease, but the scope of the present disclosure is not limited thereto.

The decoder circuit 240 may control the operations of the pull-up current generator 210 and the pull-down current generator 220. For example, the decoder circuit 240 may transmit a first decoder signal (D1) to the pull-up current generator 210 and may transmit a second decoder signal (D2) to the pull-down current generator 220, so that the operations of the pull-up current generator 210 and the pull-down current generator 220 are controlled. Specifically, the decoder circuit 240 may turn on at least a portion of the pull-up current cells, and may then sequentially turn off the turned-on pull-up current cells. In addition, when all of the pull-up current cells are turned off, the decoder circuit 240 may sequentially turn on at least a portion of the pull-down current cells.

The decoder circuit 240 may control the pull-up current generator 210 and the pull-down current generator 220 based on a noise distribution of the ramp signal (RS). For example, the decoder circuit 240 may reduce the number of pull-up current cells to be turned on as the magnitude of a first noise required at the start time point of the ramp signal (RS) decreases. In addition, the decoder circuit 240 may increase the number of pull-up current cells to be turned on as the magnitude of a second noise required at the end time point of the ramp signal (RS) decreases. When the magnitude of a third noise required at an intermediate time point (i.e., a midpoint) between the start time point and the end time point of the ramp signal (RS) is at a minimum value, the decoder circuit 240 may control the pull-up current generator 210 and the pull-down current generator 220 such that the number of pull-up current cells to be turned on is equal to the number of pull-down current cells to be turned on. More detailed descriptions of how the decoder circuit 240 controls the pull-up current generator 210 and the pull-down current generator 220 will be provided herein below with reference to the attached drawings.

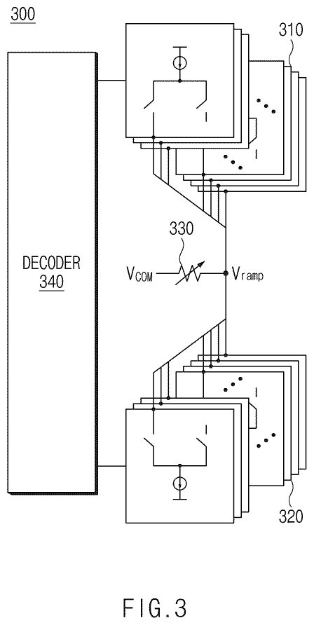

FIG. 3 is a diagram illustrating an example of a ramp generator 300 according to an embodiment of the present disclosure.

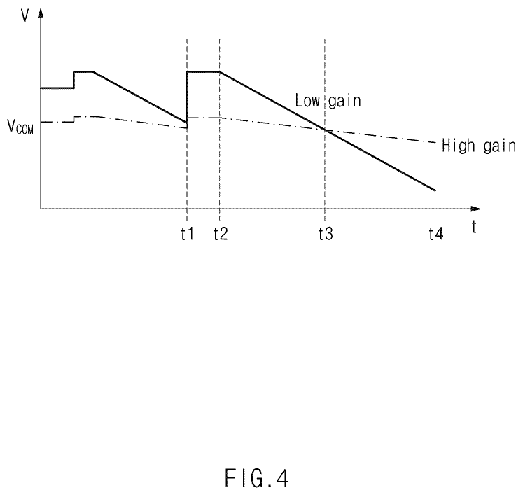

FIG. 4 is a diagram illustrating an example of a ramp signal based on according to an embodiment of the present disclosure.

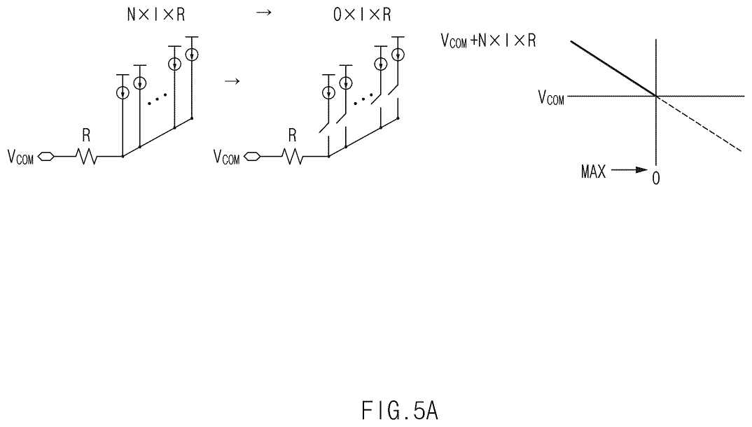

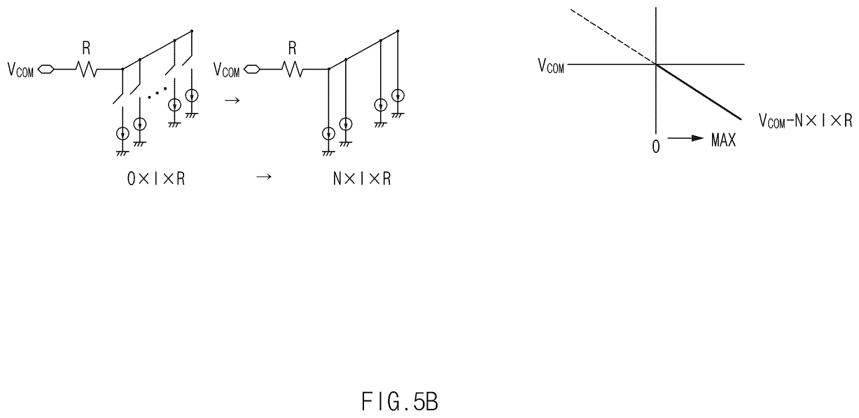

FIG. 5A and FIG. 5B are diagrams illustrating example operations of the ramp generator according to an embodiment of the present disclosure.

Hereinafter, the ramp generator of FIG. 3 will be described in detail with reference to FIG. 4 5A and 5B.

Referring to FIG. 3, the ramp generator 300 may include pull-up current cells 310, pull-down current cells 320, a variable resistor 330, and a decoder 340. The ramp generator 300 of FIG. 3 may be an embodiment of the ramp generator 130 of FIG. 1.

A power-supply voltage may be applied to the pull-up current cells 310.

A ground voltage may be applied to the pull-down current cells 320.

One end of the variable resistor 330 may be connected to the pull-up current cells 310 and the pull-down current cells 320, and may output a ramp signal (Vᵣₐₘₚ). Additionally, a common voltage (V_{COM}) may be applied to the other end of the variable resistor 330.

Referring to FIG. 4, when the pull-up current cells 310 connected to the power-supply voltage are turned on, the magnitude of a voltage of the ramp signal (Vᵣₐₘₚ) may increase above the common voltage (V_{COM}) at a time point (t1). For convenience of description, the time point (t1) may be referred to as the start time point of the ramp signal (Vᵣₐₘₚ). The magnitude of the rising voltage may be proportional to the number of pull-up current cells 310 to be turned on. For example, referring to FIG. 5A, assuming that the resistance value of the variable resistor is denoted by ‘R’, the magnitude of the current generated by each pull-up current cell is denoted by ‘I’, and N pull-up current cells are turned on, the voltage magnitude of the ramp signal (Vᵣₐₘₚ) may be represented as an equation “V_{COM}+N×I×R”.

As the pull-up current cells 310 turned on at a time point (t2) are sequentially turned off one by one, the voltage magnitude of the ramp signal (Vᵣₐₘₚ) may gradually decrease.

At a time point (t3) where all of the pull-up current cells 310 are turned off, the voltage magnitude of the ramp signal (Vᵣₐₘₚ) may be equal to the magnitude of the common voltage (V_{COM}). At the time point (t3) where all of the pull-up current cells 310 are turned off, the pull-down current cells 320 to which a ground voltage is applied may be sequentially turned on one by one. As the number of turned-on pull-down current cells 320 increases, the voltage magnitude of the ramp signal (Vᵣₐₘₚ) may gradually decrease.

For convenience of description, the time point where the determined number of pull-down current cells are turned on will hereinafter be referred to as the end time point of the ramp signal (Vᵣₐₘₚ), and may correspond to a time point (t4) of FIG. 4. Referring to FIG. 5B, assuming that the magnitude of the current generated by each pull-down current cell is denoted by ‘I’ and that N pull-down current cells 320 are turned on, the voltage magnitude of the ramp signal (Vᵣₐₘₚ) at the time point (t4) may be represented as an equation “V_{COM}−N×I×R”.

Thereafter, when all the pull-down current cells 320 are turned off and the pull-up current cells 310 are turned on, the ramp signal (Vᵣₐₘₚ) having a rising voltage level may be output at the time point (t1).

A slope, voltage magnitude, etc., of the ramp signal (Vᵣₐₘₚ) may be determined by the resistance value of the variable resistor 330. Additionally, the resistance value of the variable resistor 330 may be determined based on the gain of the image sensing device 100. For example, referring to FIG. 4, the resistance value of the variable resistor 330 when a high gain is required in the image sensing device 100 may be greater than the resistance value of the variable resistor 330 when a low gain is required in the image sensing device 100.

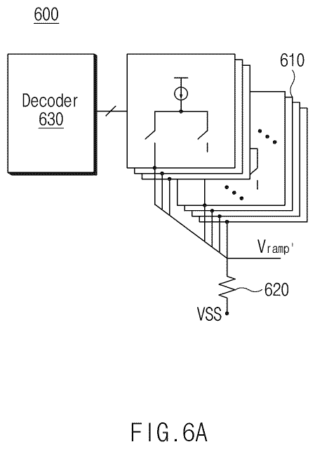

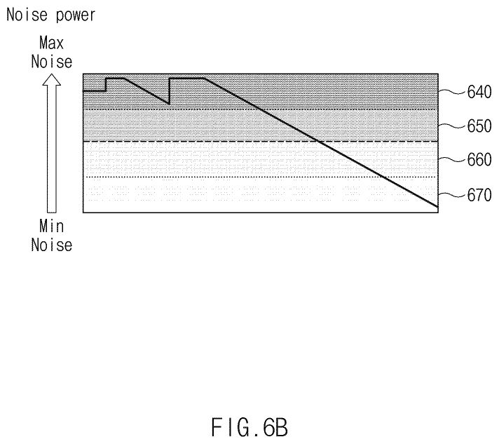

FIG. 6A and FIG. 6B are diagrams illustrating an example of noise distribution of the ramp signal according to a comparative example.

Referring to FIG. 6A, a ramp generator 600 according to the comparative example may include pull-up current cells 610, a resistor 620, and a decoder 630. One end of the resistor 620 may be connected to the pull-up current cells 610, and the other end of the resistor 620 may be connected to a ground voltage (VSS). The ramp generator 600 may turn on the pull-up current cells 610 to generate a ramp signal (V_{ramp′}). Additionally, the ramp generator 600 may create the slope of the ramp signal (V_{ramp′}) by sequentially turning off the turned-on pull-up current cells 610 one by one until all the pull-up current cells 610 are turned off. Since noise of the ramp signal (V_{ramp′}) may be generated by the pull-up current cells 610, the noise of the ramp signal (V_{ramp′}) may be proportional to the number of pull-up current cells 610 to be turned on. Therefore, referring to FIG. 6B, noise generated in a time section 670 of the ramp signal (V_{ramp′}) may be less than noise generated in a time section 660 of the ramp signal (V_{ramp′}), the noise generated in the time section 660 of the ramp signal (V_{ramp′}) may be less than noise generated in the time section 650 of the ramp signal (V_{ramp′}), and the noise generated in the time section 650 of the ramp signal (V_{ramp′}) may be less than noise generated in a time section 640 of the ramp signal (V_{ramp′}).

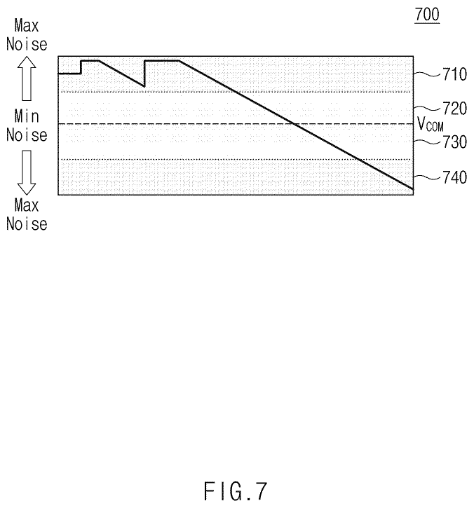

FIG. 7 is a diagram illustrating an example of the noise distribution 700 of the ramp signal based on some embodiments of the present disclosure.

Hereinafter, the noise distribution 700 of FIG. 7 will be described in detail with reference to FIGS. 3 and 6.

The ramp generator 300 of FIG. 3 may generate a ramp signal (Vᵣₐₘₚ) corresponding to the ramp signal (V_{ramp′}) generated by the ramp generator 600 of FIG. 6. For example, in a situation where the current generated by each current cell included in the ramp generator 300 has the same magnitude as the current generated by each current cell included in the ramp generator 600, and the resistor of the ramp generator 300 has the same resistance value as the resistor of the ramp generator 600, assuming that the ramp generator 600 turns on a total of 1500 pull-up current cells 610 to generate the ramp signal (V_{ramp′}) and then sequentially turns off the 1500 turned-on pull-up current cells 610 one by one, the ramp generator 130 may generate the ramp signal (Vᵣₐₘₚ) by turning on 750 (corresponding to, for example, half of the 1500) pull-up current cells 310 and 750 pull-down current cells 320. Specifically, in a situation where the ramp generator 300 turns on 750 pull-up current cells 310 and then sequentially turns off the 750 turned-on pull-up current cells 310 one by one, when all of the pull-up current cells 310 are turned off, the ramp generator 300 may turn on up to 750 pull-down current cells 320 one by one. As the number of turned-on current cells in the ramp generator 300 is different from the number of turned-on current cells in the ramp generator 600, the noise distribution of the ramp signal (Vᵣₐₘₚ) may also be different from the noise distribution of the ramp signal (V_{ramp′}). Specifically, referring to FIG. 7, since 750 pull-up current cells 310 and 750 pull-down current cells 320 are turned on, a symmetric noise distribution may be created based on the common voltage (V_{COM}). In other words, noise generated in a time section 720 may correspond to noise generated in a time section 730, and noise generated in a time section 710 may correspond to noise generated in a time section 740. Moreover, since a total of 1500 pull-up current cells of the ramp generator 600 must be turned on, a maximum level of noise generated by the ramp generator 600 may be greater than a maximum level of noise generated by the ramp generator 300 in which a total of 750 current cells is turned on at a time. In other words, as the ramp generator 300 includes not only the variable resistor 330 to which the common voltage is applied, but also the pull-up current cells 310 and the pull-down current cells 320, the ramp generator 130 can reduce the number of current cells that must be turned on at once, resulting in reduction in the magnitude of noise in the ramp signal (Vᵣₐₘₚ). The above numerical values are merely examples for convenience of explanation, and the scope of embodiments of the present disclosure is not limited thereto.

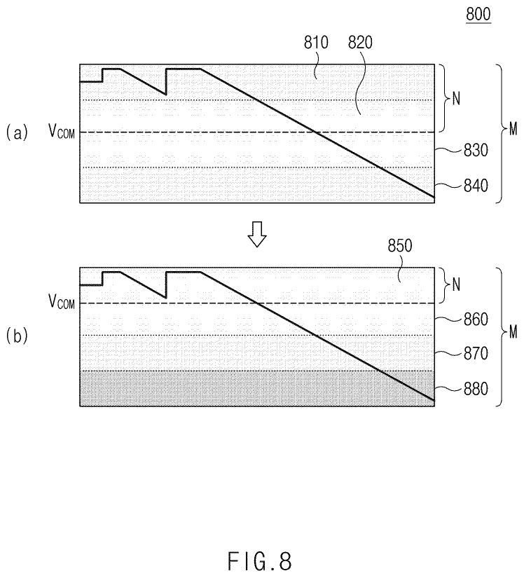

FIG. 8 is a diagram illustrating an example of the noise distribution 800 of the ramp signal based on some embodiments of the present disclosure.

Hereinafter, the noise distribution 800 of FIG. 8 will be described in detail with reference to FIG. 3.

Referring back to FIG. 3, the ramp generator 300 may adjust the number of current cells to be turned on and off under the control of the decoder 340. For example, the decoder 340 may determine whether to turn on or off the pull-up current cells 310 and pull-down current cells 320 based on the noise distribution of the ramp signal (Vᵣₐₘₚ).

For example, assuming that the ramp generator 300 generates the ramp signal (Vᵣₐₘₚ) using a total of M current cells, the decoder 340 may turn on N pull-up current cells 310 and may then turn on (M-N) pull-down current cells 320. The noise distribution of the ramp signal (Vᵣₐₘₚ) may vary depending on the number (N) of pull-up current cells 310 to be turned on by the decoder 340. (a) of FIG. 8 is a graph of the ramp signal (Vᵣₐₘₚ) when 750 pull-up current cells 310 and 750 pull-down current cells 320 are turned on (i.e., N=750), assuming that the ramp generator 300 uses a total of 1500 current cells to generate the ramp signal (Vᵣₐₘₚ) (i.e., M=1500). (b) of FIG. 8 is a graph of the ramp signal (Vᵣₐₘₚ) when 375 pull-up current cells 310 are turned on and 1125 pull-down current cells 320 are turned on (i.e., N=375). Since the number of turned-on current cells for each time section in (a) of FIG. 8 is different from the number of turned-on current cells for each time section in (b) of FIG. 8, the noise distribution of the ramp signal (Vᵣₐₘₚ) of (a) of FIG. 8 may be different from the noise distribution of the ramp signal (Vᵣₐₘₚ) of (b) of FIG. 8. For example, since the number of turned-on pull-up current cells 310 in a time section 810 is greater than the number of turned-on pull-up current cells 310 in a time section 850, the magnitude of noise in the ramp signal (Vᵣₐₘₚ) in the time section 810 may be greater than the magnitude of noise in the ramp signal (Vᵣₐₘₚ) in the time section 850. Additionally, the graph indicating the number of turned-on pull-up current cells 310 in a time section 820 is vertically symmetrical to the graph indicating the number of turned-on pull-down current cells 320 in a time section 860, so that the graph indicating the magnitude of noise in the ramp signal (Vᵣₐₘₚ) in the time section 820 is also vertically symmetrical to the graph indicating the magnitude of noise in the ramp signal (Vᵣₐₘₚ) in the time section 860. In addition, since the number of turned-on pull-down current cells 320 in a time section 830 is less than the number of turned-on pull-down current cells 320 in a time section 870, the magnitude of noise in the ramp signal (Vᵣₐₘₚ) in the time section 830 may be less than the magnitude of noise in the ramp signal (Vᵣₐₘₚ) in the time section 870. Moreover, since the number of turned-on pull-down current cells 320 in a time section 840 is less than the number of turned-on pull-down current cells 320 in a time section 880, the magnitude of noise in the ramp signal (Vᵣₐₘₚ) in the time section 840 may be less than the magnitude of noise in the ramp signal (Vᵣₐₘₚ) in the time section 880. In conclusion, the magnitude of noise in the ramp signal (Vᵣₐₘₚ) in the time section 880 in which the largest number of current cells are turned on among the plurality of time sections may be at a maximum value, and the magnitude of noise in the ramp signal (Vᵣₐₘₚ) in each of the time sections (820, 830, 850, 860) in which the smallest number of current cells is turned on among the plurality of time sections may be at a minimum value. That is, the ramp generator 130 or 300 according to an embodiment of the present disclosure may adjust the number of current cells to be turned on according to the noise distribution of a required ramp signal. The above-described numerical values are merely examples for convenience of explanation, and the scope of embodiments of the present disclosure is not limited thereto.

As is apparent from the above description, the ramp generator according to the embodiments of the present disclosure may reduce noise of the ramp signal.

The ramp generator according to the embodiments of the present disclosure may change the noise distribution of the ramp signal.

The embodiments of the present disclosure may provide a variety of effects capable of being directly or indirectly recognized through the above-mentioned disclosure.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in the present disclosure.

What is claimed is:

1. A ramp generator comprising:
a pull-up current generator configured to generate a pull-up current;
a pull-down current generator configured to generate a pull-down current; and
a variable resistor circuit, one end of which is connected between the pull-up current generator and the pull-down current generator and configured to output a ramp signal, and another end of which is configured to receive a common voltage.

2. The ramp generator according to claim 1, wherein:
the pull-up current generator includes a plurality of pull-up current cells; and
the pull-down current generator includes a plurality of pull-down current cells.

3. The ramp generator according to claim 2, further comprising: a decoder circuit configured to control operations of the pull-up current generator and the pull-down current generator,
wherein the decoder circuit is configured to:
turn on at least a portion of the pull-up current cells and then sequentially turn off the turned-on portion of the pull-up current cells.

4. The ramp generator according to claim 3, wherein the decoder circuit is configured to:
sequentially turn on at least a portion of the pull-down current cells, in response to a determination that all of the pull-up current cells are turned off.

5. The ramp generator according to claim 3, wherein the decoder circuit is configured to:
control operations of the pull-up current generator and the pull-down current generator based on a noise distribution of the ramp signal.

6. The ramp generator according to claim 5, wherein the decoder circuit is configured to:
reduce a number of pull-up current cells to be turned on, in response to a decrease in a magnitude of a first noise required at a start point of the ramp signal.

7. The ramp generator according to claim 5, wherein the decoder circuit is configured to:
increase a number of pull-up current cells to be turned on, in response to a decrease in a magnitude of a second noise required at an end point of the ramp signal.

8. The ramp generator according to claim 5, wherein the decoder circuit is configured to:
in response to a determination that a magnitude of a third noise required at a midpoint between a start point and an end point of the ramp signal is at a minimum value, control the pull-up current generator and the pull-down current generator such that a number of pull-up current cells to be turned on is equal to a number of pull-down current cells to be turned on.

9. The ramp generator according to claim 1, wherein:
the pull-up current generator is configured to receive a power-supply voltage; and
the pull-down current generator is configured to receive a ground voltage.

10. The ramp generator according to claim 1, wherein:
the variable resistor circuit is configured to have a resistance value that varies depending on a gain required by an image sensing device.

11. The ramp generator according to claim 10, wherein:
the variable resistor circuit is configured to have a smaller resistance value as a magnitude of the required gain increases.

12. A ramp generator comprising:
a plurality of pull-up current cells configured to receive a power-supply voltage;
a plurality of pull-down current cells configured to receive a ground voltage; and
a variable resistor, one end of which is connected between the pull-up current cells and the pull-down current cells and configured to output a ramp signal, and another end of which is configured to receive a common voltage.

13. The ramp generator according to claim 12, further comprising:
a decoder connected to the pull-up current cells and the pull-down current cells,
wherein the decoder is configured to:
turn on at least a portion of the pull-up current cells and then sequentially turn off the turned-on portion of the pull-up current cells.

14. The ramp generator according to claim 13, wherein the decoder is configured to:
sequentially turn on at least a portion of the pull-down current cells, in response to a determination that all of the pull-up current cells are turned off.

15. The ramp generator according to claim 13, wherein the decoder is configured to:
control operations of the pull-up current cells and the pull-down current cells based on a noise distribution of the ramp signal.

16. The ramp generator according to claim 15, wherein the decoder is configured to:
reduce a number of pull-up current cells to be turned on, in response to a decrease in a magnitude of a first noise required at a start point of the ramp signal.

17. The ramp generator according to claim 15, wherein the decoder is configured to:
increase a number of pull-up current cells to be turned on, in response to a decrease in a magnitude of a second noise required at an end point of the ramp signal.

18. The ramp generator according to claim 15, wherein the decoder is configured to:
in response to a determination that a magnitude of a third noise required at a midpoint between a start point and an end point of the ramp signal is at a minimum value, control a number of pull-up current cells to be turned on to be equal to a number of pull-down current cells to be turned on.

19. The ramp generator according to claim 12, wherein:
the variable resistor is configured to have a resistance value that varies depending on a gain required by an image sensing device.

20. A ramp generator comprising:
a plurality of pull-up current cells configured to receive a power-supply voltage;
a plurality of pull-down current cells configured to receive a ground voltage;
a variable resistor having one end configured to output a ramp signal and another end configured to receive an applied common voltage, such that a resistance value of the variable resistor is determined based on a number of the pull-up current cells to be turned on and a number of the pull-down current cells to be turned on; and
a decoder configured to control operations of the pull-up current cells and the pull-down current cells.
